(19) United States
(12) Patent Application Publication
(10) Pub. No.: US 2006/0186872 A1
(43) Pub. Date: Aug. 24, 2006

(54) Electric field detector

(76) Inventor: Mark Trethewey, (US)

Correspondence Address: Deepwater Electronics, 27 Young Street, Deepwater, 2371, AU

(21) Appl. No.: 11/063,298

(22) Filed: Feb. 22, 2005

(51) Int. Cl. G01R 31/00

(52) U.S. Cl. 324/96

(57) ABSTRACT

The present invention relates to an improved method to detect electric field intensity. It is a generational improvement on free body field detectors and uses a ferrite sensor element to increase detector capacitance and hence signal output. This configuration also provides reduced detector volume, increased stability and a reduction in susceptibility to capacitive coupling. This system provides an output signal proportional to the electric field strength integrated over the volume of the ferrite detector element. Further this system is low cost and passive. A passive system uses no supply power and does not suffer from increased noise floor characteristics like active devices.

### BACKGROUND

In the past, time harmonic electric fields were detected using free-body electric field meters. These detectors were typically of spherical or cubic geometry and were constructed from conductive material. When placed in a time harmonic electric field a charge will oscillate between two electrically isolated halves of the detector. Mathematically this charge can be described by:
Q=A·ε_{o·}E

Where: εₒ=permittivity of free space
E=electric field strength to be detected
A=a constant proportional to detector surface area
Q=charge on detector

To achieve useful detector sensitivity the detector dimensions are typically in the order of 10 cm (4 inches.)

Due to the large surface areas of these detectors they are very prone to stray capacitive coupling to other bodies in their proximity. This can modify the capacitance of the detector assembly, and the above equation can be re-arranged to:
Q=C·d·E

Where: C=total capacitance of detector
d=spacing between detector halves
Q & E as above

Hence it can be observed that the output of the detector is directly related to the capacitance of the detector. So any modification of detector capacitance by stray capacitive coupling will modify the detector output, thus giving false readings.

### DISCLOSURE OF THE INVENTION

It is the aim of the present invention to eliminate or at least minimise the foregoing disadvantages and also to enhance certain desirable characteristics of free body electric field detectors.

If a stable known capacitance can be intrinsically added to the detector then the output of the detector is proportionally increased. If this can be achieved with a physically smaller detector then the effects of stray coupling capacitance are reduced by two mechanisms. Firstly the area of the detector is reduced thus directly reducing coupling capacitance. This is evident from the basic capacitor equation:
C=(ε·A)/D

Where: C=capacitance
ε=permittivity
A=area of conductive plates
D=plate separation

Secondly, if the intrinsic capacitance of the detector is large in relation to the coupling capacitance, then the effect of the coupling capacitance is minimised. This occurs because the coupling capacitance can now only make a small percentage change in the total detector capacitance.

If we consider two cube shaped conductive boxes separated by a small distance, it can be shown that relatively large dimensions are required to achieve sufficient detector capacitance. Further, only the outer surface of the cubes are significant because the conductive material acts as a Faraday shield, hence excluding any electric field from their internal volumes.

However, ferrites have some interesting properties in this regard. Most ferrites are relatively poor conductors and allow electric fields to penetrate into their internal volumes, hence minimizing the Faraday shield effect and allowing the sensor to detect electric field in a space volume. Pre-existing designs only detected electric field over the surface area of the detector.

At this stage it is convenient to consider a ferrite structure being composed of metal particles entrapped in a ceramic substrate. Referring to FIG. 1 we can propose an electrical equivalent circuit for such a model. The metallic particles act as capacitor plates with the ceramic substrate acting as a dielectric. Ferrite has volume resistivity and is modeled by parallel resistances. As shown a network of resistor/capacitor elements can be built up. The ferrites proposed are the MnZn type which have a classic spinel atomic lattice structure. At a microscopic scale the resistivity of this structure is not homogenous, with the resistivity of the grain boundaries being typically a million times that of the ferrite within the grains. Typical grain sizes range from 5 to 40 um, with the grain boundaries having an enrichment of Ca, Si and Ti ions which produces a high resistivity boundary of approximately 10 angstrom units width. This grain structure has a dominant influence on the effective permittivity of the ferrite. Such ferrites are, in effect, compound dielectrics composed of very thin high resistivity grain boundaries separating semi-conducting grains of low resistivity, with a resulting effective permittivity as high as 100,000. Remember that capacitance is directly related to permittivity. FIG. 1 shows a conceptual view of four grains in a ferrite structure, and indicates the associated resistivity and capacitance between the grains as R′ and C′ respectively.

From this it can be deduced that ferrite has both volume resistivity and volume capacitance. FIG. 2 shows a macroscopic equivalent circuit for a volume of ferrite. The values Cv and Rv are the algebraic addition of all the R′ and C′ values for all grains in the ferrite volume.

Now referring to FIG. 3 if the ferrite equivalent circuit is arranged so it is in parallel with the detector plate capacitance then the total capacitance is increased.

That is:
Cₛₑₙₛₒᵣ=Cₚ+Cᵥ

But as shown previously the charge Q generated in a given field is directly proportional to the capacitance.

The volume resistivity of the ferrite and the increased inductance of the assembly damps the sensor capacitance, improving output stability and discriminating high frequency noise.

The sensor plates have a fiberglass dielectric which increases the value of Cₚ by a factor of εᵣ for fiberglass. It is also important to correctly condition the sensor output signal with suitable electronics. By monitoring current output from the sensor rather that voltage, some loss of sensitivity occurs but there is a marked improvement in detector output stability and discrimination of stray effects. The current out of the sensor is equal to the time derivative of the charge, and for time harmonic electric fields it can be written:
l=jωAEε

Where:
j=complex operator E=electric field
ω=angular frequency A=area
ε=permittivity

### DESCRIPTION OF THE DRAWINGS

FIG. 1—Schematic equivalent circuit of ferrite microstructure

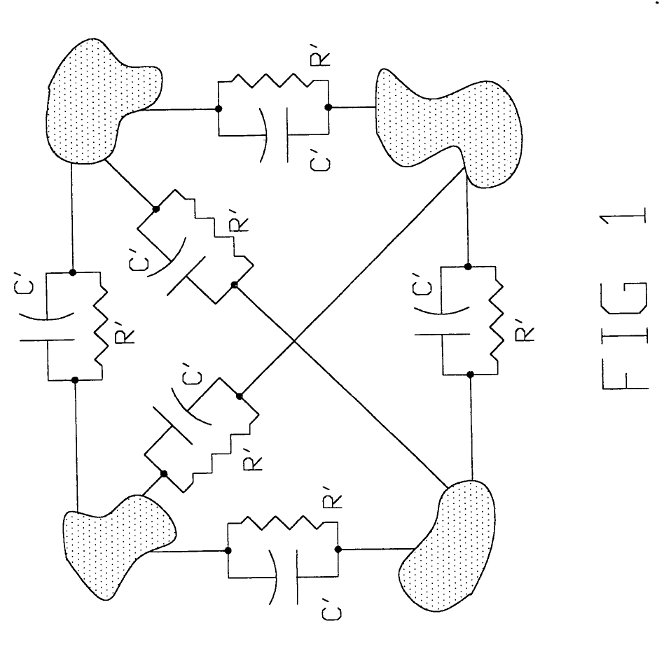

FIG. 2—Schematic equivalent circuit of ferrite macrostructure

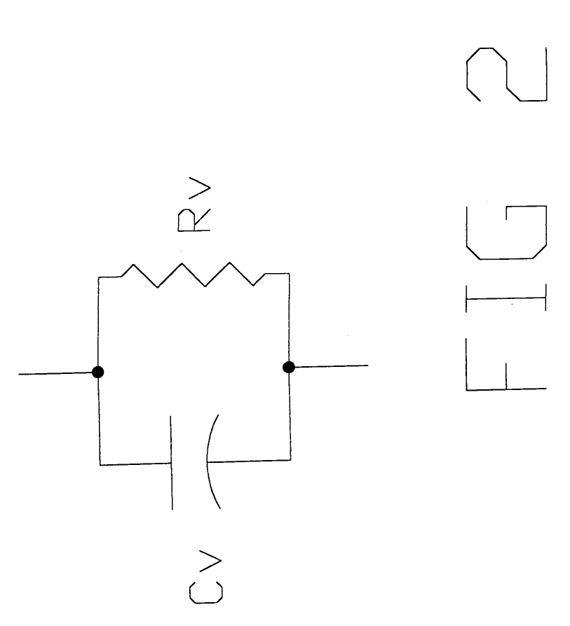

FIG. 3—Schematic equivalent circuit of detector

FIG. 4—Schematic of detector signal conditioning circuit

FIG. 5—Sectioned elevation view of detector cross-section

FIG. 6—Exploded perspective view of the sensor

### DESCRIPTION OF THE INVENTION

One preferred form of the invention will now be described by way of example, notwithstanding any other forms that may fall within the scope of the invention.

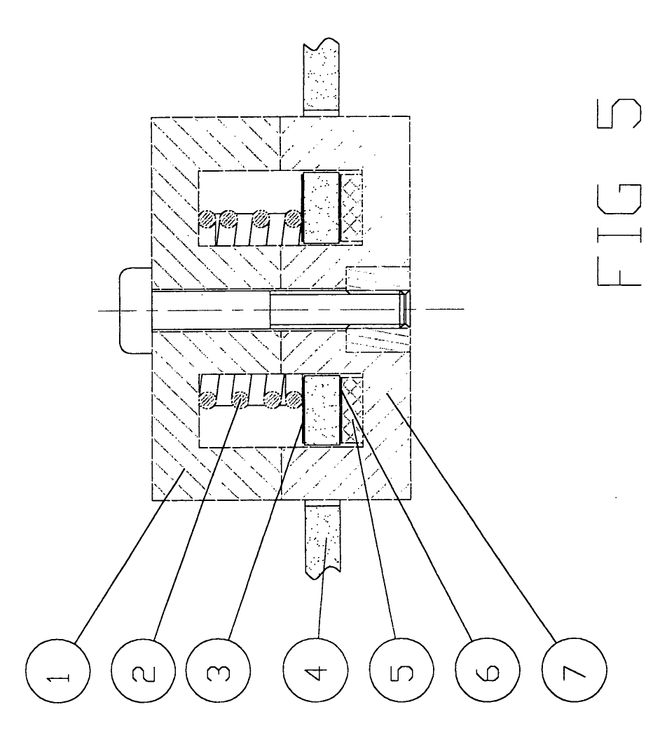

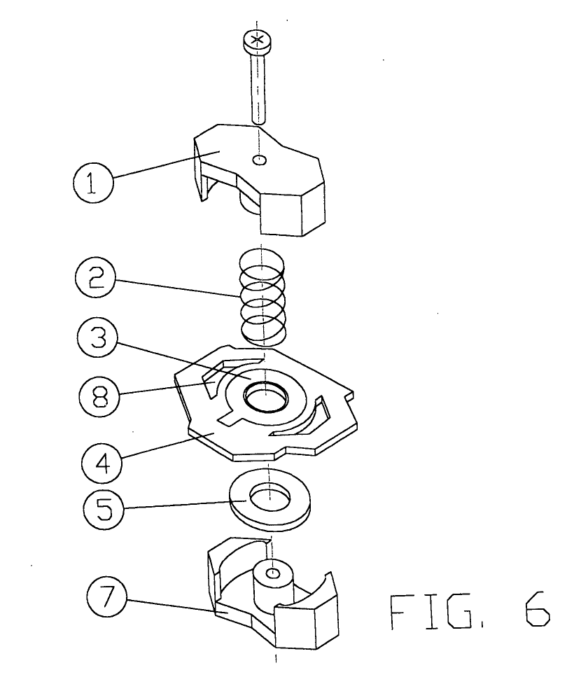

Referring to FIGS. 5 and 6, the sensor consists of an upper ferrite pole piece (1), a lower ferrite pole piece (7), an insulation washer (5), contact spring (2), fiberglass board (4) and copper sheets (3) and (6).

The sensor is designed to be an integral part of a printed circuit board, with the fiberglass board (4) being the basic substrate of the printed circuit board. The copper sheets (3) and (6) are specially shaped sections of track on the top and bottom sides of the printed circuit board. The printed circuit board has holes (8) routed in it to allow the lower ferrite pole piece (7) to fit up through it. The copper sheets (3) and (6) are etched so they have a small clearance between their edges and the walls of the lower ferrite pole piece (7), thus ensuring they remain insulated.

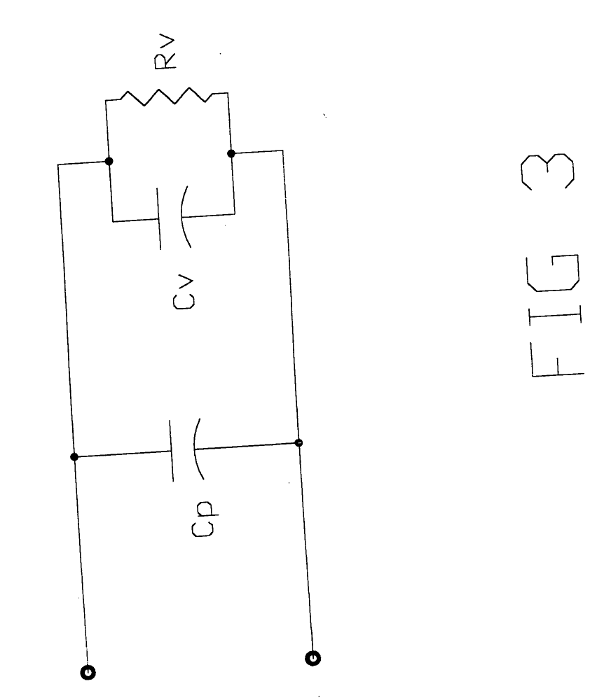

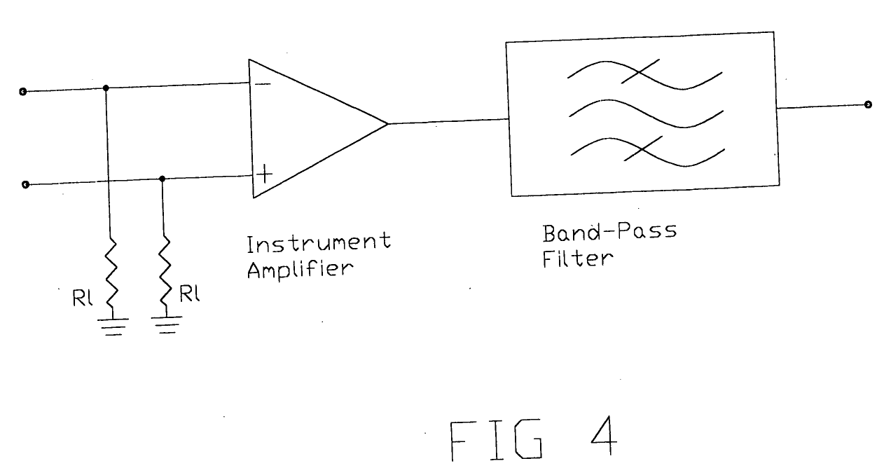

The copper sheets (3) and (6) are the main detection plates and in conjunction with the dielectric formed by the fiberglass board (4) which separates them, they produce the capacitance Cp shown in FIG. 3. Electrical connections are provided between the copper sheets (3) and (6) and the inputs to the instrument amplifier shown in FIG. 4.

Again referring to FIG. 3 the capacitance C_{V} and resistance R_{V} are produced by the upper and lower ferrite pole pieces (1) and (7). Insulating washer (5) insulates copper sheet (6) from the lower ferrite pole piece (7). Copper sheet (3) has a bright tinned surface which ensures a reliable electrical connection with the contact spring (2). The upper end of contact spring (2) forms an electrical connection with the upper ferrite pole piece (1).

Referring to FIG. 4, the inputs of the instrument amplifier are resistively loaded to ground by two high value resistors. In effect the instrument amplifier now senses the voltages generated across the two resistors by the output current of the sensor when it is subjected to a time harmonic electric field. The magnitude of the sensor output current, and hence the magnitude of the voltage generated, is proportional to the applied electric field strength.

The output of the instrument amplifier passes through a narrow band-pass filter that selects the particular frequency of time harmonic field to be detected. This improves reliability by rejecting out of band or spurious signals that could cause incorrect detector outputs.

It should be noted that this is a passive detection system. A passive system does not consume any supply current hence allowing micro-powered systems to be constructed using this sensor. A further important advantage of passive systems is that they do not contribute to system electrical noise floor characteristics to the same extent as active sensors. An electrically quieter system allows the measurement of lower electric field intensities with greater reliability.

The output of the detection system could be used to trigger a multitude of systems or devices. However one system of note is an audible warning device that is controlled by circuitry or a micro-controller which produces a series of fixed length beeps with the beep time spacing inversely proportional to detected field strength.

A further application is in vehicular systems where the electric field detector is mounted at a remote exposed point of the vehicle, and the audible warning device is mounted inside the operator cabin. Communication between the electric field detector and the audible warning device could be via a low power radio frequency link, with the detector unit incorporating a re-chargeable battery and solar cell array. This eliminates the need for costly and difficult wiring between the units.

Further applications potentially exist in guidance systems that use electric field sensors.

1. An electric field intensity detector comprising:
a ferrite element as the major detection element, wherein the ferrite micro-structure inherently improves detector output signal levels and stability; and
means for detecting charge induced on the ferrite element by a time harmonic electric field comprising a printed circuit board with appropriately placed copper sections on the upper and lower side; and
means for fixing the ferrite member in relation to the printed circuit board and for providing an electrical connection between the ferrite and one of the copper sections; and
circuitry to monitor the induced voltages on the copper sections on the printed circuit board, and produce a stable time harmonic output voltage proportional to the incident time harmonic electric field intensity.

2. An electric field intensity detector, as in claim 1, that integrates the field intensity over the ferrite detector element volume by:
allowing the electric field to penetrate into the volume of the ferrite due to its relatively high resistivity and hence poor Faraday shielding effect; and
using the grains in the ferrite to act a miniature free body electric field detectors; and
using the intrinsic resistance and capacitance between the ferrite grains to algebraically add the charges induced on each grain and conduct a charge flow to a connection point on the ferrite.

3. A electric field intensity detector, as in claims 1 and 2, that achieves high intrinsic capacitance and hence high output signal levels by using the dielectric properties of ferrite.

4. A electric field intensity detector, as in claims 1 and 2, that minimizes the effects of stray coupling capacitance by.
reducing the physical size of the detector which reduces the surface area for any coupling to act on and hence reduces coupling capacitance; and
by increasing the capacitance of the sensor which will swamp any small coupling capacitance resulting in minimal net capacitance change, and hence minimal signal output disturbance.

5. A passive electric field intensity detector system, as in claims 1 and 2, that requires no power supply, hence making it suitable for use in micro-powered applications.

6. A detector, as in claims 1 and 2, that achieves a high signal output with a very compact physical format making it suitable for miniaturized, low weight applications.

7. A passive detector system, as in claim 1, that has a low intrinsic noise factor.

8. A low cost detector system, as in claim 1, that can be constructed using readily available components.

9. A detector system, as in claim 1, that intrinsically provides signal damping, thus reducing spurious outputs, with this damping being achieved by utilizing the resistive properties of the ferrite element and the inductance of the physical assembly.

10. An electric field intensity detector, as in claim 1, that utilizes the micro-structure of ferrite to enhance detector output, stability and noise while reducing size, cost and weight.
